(19) United States
(12) Patent Application Publication
(10) Pub. No.: US 2017/0269858 A1
(43) Pub. Date: Sep. 21, 2017

(54) METHOD AND SYSTEM FOR DATA PROTECTION IN NVMe INTERFACE

(71) Applicant: SAMSUNG ELECTRONICS CO., LTD., SUWON-SI (KR)

(72) Inventor: Venkataratnam NIMMAGADDA, BENGALURU (IN)

(21) Appl. No.: 15/346,782

(22) Filed: Nov. 9, 2016

(30) Foreign Application Priority Data
Mar. 18, 2016 (IN) 201641009471

(51) Int. Cl. G06F 3/06; G06F 11/10; G11C 29/52; H03M 13/09

(52) U.S. Cl. CPC G06F 3/0619; H03M 13/09; G06F 3/064; G06F 3/0647; G06F 3/0665; G06F 3/0679; G06F 11/1004; G06F 11/1068; G11C 29/52

(57) ABSTRACT

Data transfer in an NVMe interface includes a device in a system receiving a data transfer command from a host in the system. The device collects all logical blocks (LB) and corresponding metadata (MD) information in response to the received command. The device transfers metadata-logical block data pair(s) between the host and device in data integrity extension mode.

### CROSS-REFERENCE TO RELATED APPLICATION

This application claims priority under 35 U.S.C. §119 to Indian Patent Application No. 201641009471, filed on Mar. 18, 2016 in the Indian Intellectual Property Office, the disclosure of which is incorporated by reference in its entirety.

### BACKGROUND

1. Field of the Disclosure

The present disclosure relates to data storage systems. More particularly, the present disclosure relates to data protection in data storage systems.

2. Background Information

Non-Volatile Memory Express (NVMe) is a communication interface protocol developed for Solid State Devices (SSD). NVMe defines a specification for accessing SSDs attached through a Peripheral Component Interconnect Express (PCI Express) bus. Like other communication interfaces, NVMe also is equipped with provisions to ensure data security/protection. One popular data protection technology widely being used is data integrity extension (DIX). Data integrity extension allows a data integrity check based on a checksum value associated with the data being communicated. A host that works in data integrity extension mode stores logical blocks (LBs) of the actual data being communicated and protection information that is metadata (MD). The host stores the LBs in a logical block addressing (LBA) host buffer (i.e., an LBA host buffer), and the MD in a metadata host buffer (MD host buffer). The device reads data of the LB(s) continuously from the LBA host buffer, and the protection information of the MD(s) continuously from the MD host buffer.

While the data integrity extension mode of operation ensures end to end data integrity and protection, there are certain disadvantages at an implementation level. For example, the device, after collecting all data of an LB, needs to buffer the data of the LB internally, until the corresponding metadata is collected from the MD host buffer. Further, while certain data of the LB(s) and corresponding protection information of the MD(s) get processed, the remaining data of the LB(s) and protection information of the MD(s) are buffered in the device. The buffer requirement demands additional hardware. Further, the buffering time delays the overall error processing.

The above information is presented as background information only to help the reader to understand context of the concepts described herein. Applicants have made no determination and make no assertion as to whether any of the above might be applicable as Prior Art with regard to the present application.

### SUMMARY

The concepts described herein provide mechanisms for simplifying data protection in storage systems which support data integrity extension (DIX).

The concepts described herein provide mechanisms for generating and transferring data in the form of metadata (MD)—logical block (LB) data pairs for the storage systems that support data integrity extension.

According to some embodiments of the present disclosure, a method for data transfer in a Non-Volatile Memory Express (NVMe) interface in data integrity extension mode includes a host initiating a communication with a device. The host and device communicate in data integrity extension mode. The device further generates host addresses of a metadata (MD)—logical block (LB) data pair corresponding to data being communicated. Further, the device transfers the MD-LB data pairs during the communication. The MD-LB data pairs are transmitted sequentially.

According to some embodiments of the present disclosure, a system for data transfer in a Non-Volatile Memory Express (NVMe) interface in data integrity extension mode includes a host that initiates a communication with a device. The host and device communicate in data integrity extension mode. The device further generates host addresses of a metadata (MD)—logical block (LB) data pair corresponding to data being communicated. Further, the device transfers the generated MD-LB data pairs during the communication. The MD-LB data pairs are transmitted sequentially.

These and other aspects of the embodiments herein will be better appreciated and understood when considered in conjunction with the following description and the accompanying drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 illustrates a block diagram of a data transfer system, as disclosed in the embodiments herein;

FIG. 2 is a block diagram that depicts components of a device, as disclosed in the embodiments herein;

FIG. 3 is a data flow diagram that depicts steps involved in the process of transferring data in data integrity extension mode, using the data transfer system as disclosed in the embodiments herein; and

FIG. 4 is an example diagram which depicts data integrity extension mode data transfer between a host and a device of the data transfer system, as disclosed in the embodiments herein.

### DETAILED DESCRIPTION OF THE EMBODIMENTS

Embodiments will be described in detail with reference to the accompanying drawings. The concepts described herein, however, may be embodied in various different forms, and should not be construed as being limited only to the illustrated embodiments. Rather, these embodiments are provided as examples so that this disclosure will be thorough and complete, and will fully convey the concepts of the present disclosure to those skilled in the art. Accordingly, known processes, elements, and techniques are not described with respect to some of the embodiments of the present disclosure. Unless otherwise noted, like reference numerals denote like elements throughout the attached drawings and written description, and thus descriptions will not be repeated. In the drawings, the sizes and relative sizes of layers and regions may be exaggerated for clarity.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

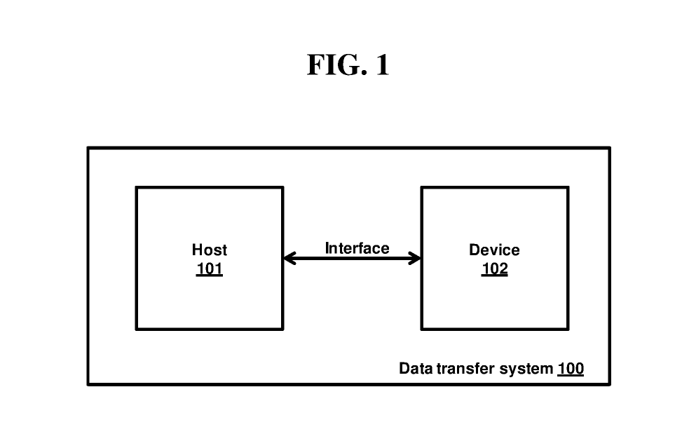

The embodiments herein disclose a mechanism for data transfer management in an NVMe interface storage system. Referring now to the drawings, and more particularly to FIGS. 1 through 4, where similar reference characters denote corresponding features consistently throughout the figures, there are shown embodiments.

FIG. 1 illustrates a block diagram of a data transfer system, as disclosed in the embodiments herein. The data transfer system 100 includes at least one host 101, and at least one device 102 connected to the at least one host 101 using a suitable interface. The interface can be any interface that meets and/or imposes requirements in terms of parameters such as, but not limited to, bandwidth, protocol, and security. For example, the interface may be an NVMe interface, or an interface of a similar type.

The host 101 can be configured to store data in any suitable format. The host 101 can be further configured to use proper memory addressing techniques to simplify data access. The host 101 can be further configured to use data integrity extension, for data integrity and protection. The host 101 can be configured to store metadata (MD) that includes a value of protection information. The protection information can be defined in terms of at least one parameter such as, but not limited to, Cyclic Redundancy Check (CRC), for protection of the actual data that is stored as logical blocks (LB).

The host 101 can issue Read/Write commands to device 102 to initiate the data transfer between host 101 and device 102. The device 102 can fetch LBs and corresponding MDs from host 101 for a Write command. The device 102 can write the LBs and corresponding MDs to host 101 for a Read command. In an embodiment, the data is transmitted as MD-LB data pairs in both read and write command cases, sequentially. The number of MD-LB data pairs can vary based on the number of the LBs and corresponding MDs that match the data being communicated between the host 101 and the device 102, as part of, the command issued by the host 101. The device 102 can be further configured to perform error check to decide whether the data is corrupted or not. The device 102 is further configured to send a response back to the host 101, wherein the response indicates whether the data is corrupted or not.

The host 101 configures the namespace of the device 102 to data integrity extension mode, using a Namespace Format command. In the data integrity extension mode, the metadata (MD) and the logical blocks (LB) in Host 101 are stored in separate buffers i.e. host metadata buffer and host logical block addressing buffer respectively. In another embodiment, the host 101 can configure the namespace of the device 102 to DIF mode, in which the MD is stored contiguous to the LB data. In another embodiment, the host 101 can format some namespaces of the device 102 in DIF mode and some other namespaces of the device 102 in data integrity extension mode. The device 102 is further configured to fetch and process data in the form of MD-LB data pairs, in the data integrity extension mode.

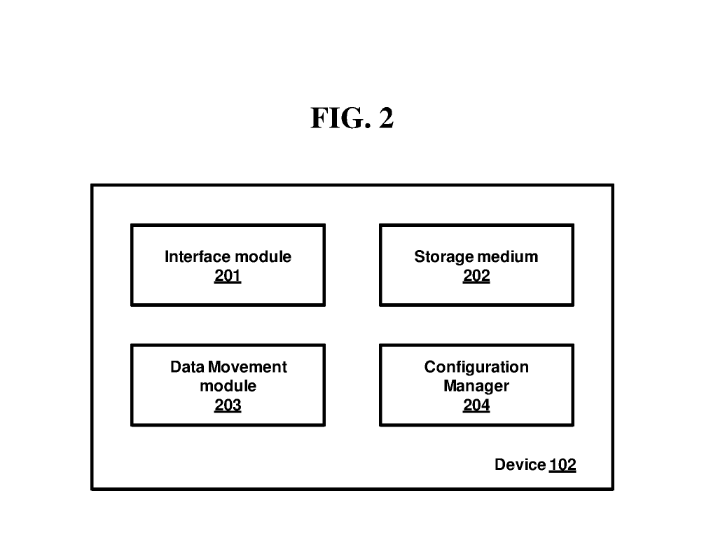

FIG. 2 is a block diagram that depicts components of a device, as disclosed in the embodiments herein. The device 102 further includes an interface module 201, a storage medium 202, a data movement module 203, and a processing module 204.

The interface module 201 can be configured to provide at least an interface for the device 102 to get connected to at least one host 101 using at least one suitable interface, i.e. a communication channel. For example, the communication channel can be based on NVMe over PCIe. The storage medium 202 can be a storage space that can store digital information following any specific guidelines defined in terms of various parameters such as, but not limited to, amount of storage space, and data security, for storing the data. The storage medium 202 can be further configured to store logical blocks (LB) as well as metadata (MD), pertaining to the data being stored. The processing module 204 can be configured to fetch and process commands from the host 101, and identify the LBs and MDs that match the received data transfer command. The processing module 204 can be further configured to instruct the data movement Module 203 to fetch MD-LB data pairs from the storage medium 202 and transfer the fetched MD-LB data pairs to the host 101, in case of a Read command. The processing module 204 can be further configured to instruct the data movement module 203 to fetch MD-LB data pairs from the host 101 and write the fetched MD-LB data pairs to the storage medium 202, in case of Write command. The data movement module 203 can be configured to operate simultaneously for both read and Write commands, based on the Interface module 201's features.

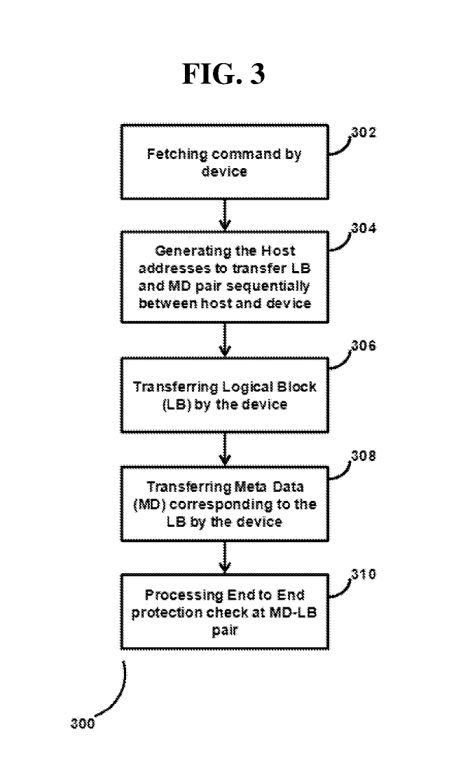

FIG. 3 is a data flow diagram that depicts steps involved in the process of transferring data in data integrity extension mode, using the data transfer system, as disclosed in the embodiments herein. The device 102 fetches (302) a data transfer command from the host 101. The device 102 processes the command, and identifies data that needs to be sent to/transferred from the host 101, in response to the data transfer command received.

The device 102 then generates (304) host addresses in order to ensure that the MD-LB data pair transfer is sequential in the data integrity extension case. The device 102 transfers (306) the LB data between host 101 and the device 102. The direction of LB data movement between host 101 and the device 102 depends on the type of the command i.e. whether the command is a Read command (RD) or a Write command (WR).

The device 102 further transfers (308) the MD data corresponding to the LB data being transmitted, between the host 101 and the device 102. The direction of MD data movement between the host 101 and the device 102 depends on the type of the command i.e. whether the command is a Read command (RD) or a Write command (WR).

The device 102 further performs (310) an End to End protection check on the MD-LB pairs. In an embodiment, the end to end protection check involves comparing a value of protection information calculated for the data transmitted, with the corresponding metadata information, for any mismatch. Any such mismatch indicates an error. Further, if any error is detected, the device 102 reports the error to the host 101, through a message such as completion entry for that command. In an embodiment, transferring the MD-LB data pair between host 101 and device 102 in data integrity extension mode involves transferring the LB and corresponding MD to separate buffers in host. Transferring the LBs and corresponding MDs together as a sequential pair to separate MD/LB host addresses in the data integrity extension mode eliminates buffering requirement, and also speeds up the overall data processing.

The various actions in method 300 may be performed in the order presented, in a different order or simultaneously. Further, in some embodiments, some actions listed in FIG. 3 may be omitted.

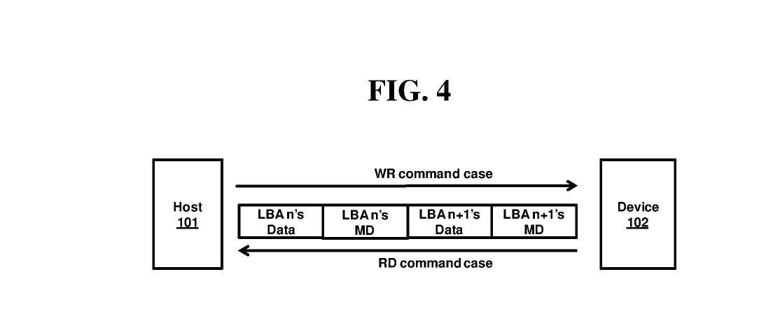

FIG. 4 is an example diagram which depicts data integrity extension mode data transfer between a host and a device of the data transfer system, as disclosed in the embodiments herein. In this mechanism, the data integrity extension mode data transfer involves sending and/or receiving data in the form of MD-LB data pairs, sequentially, between the host 101 by device 102. This order for data integrity extension mode can be followed for both RD and WR commands, by the device 102.

By allowing data transfer in the form of MD-LB data pairs in data integrity extension, the devices that support DIF mode of operation can be allowed to support data integrity extension mode of operation as well, thereby saving gate count in the device 102. Further, by eliminating a buffering requirement of MD-LB data pairs in the device 102, time required for overall data transfer and End to End Check can be reduced. Further, the transfer of data as MD-LB data pairs in data integrity extension mode reduces time taken for error handling and reporting, as any error can be immediately processed.

The embodiments disclosed herein can be implemented through at least one software program running on at least one hardware device and performing network management functions to control the network elements. The network elements shown in FIG. 1 include blocks which can be at least one of a hardware device, or a combination of a hardware device and a software module.

The embodiments disclosed herein specify a mechanism for data protection in NVMe interface. The mechanism allows transmission of logical blocks and corresponding metadata together, as MD-LB data pairs, in data integrity extension mode of operation, providing a system thereof. Therefore, it is understood that the scope of protection is extended to such a system and by extension, to a computer readable means having a message therein, the computer readable means containing a program code for implementation of one or more steps of the method, when the program runs on a server or mobile device or any suitable programmable device. The method is implemented in a preferred embodiment using the system together with a software program written in, for example Very high speed integrated circuit Hardware Description Language (VHDL), another programming language, or implemented by one or more VHDL or several software modules being executed on at least one hardware device. The hardware device can be any kind of device which can be programmed including, for example any kind of a computer like a server or a personal computer, or the like, or any combination thereof, for example one processor and two FPGAs. The device may also include means which could be for example hardware means like an ASIC or a combination of hardware and software means, an ASIC and an FPGA, or at least one microprocessor and at least one memory with software modules located therein. Thus, the means are at least one hardware means or at least one hardware-cum-software means. The method embodiments described herein could be implemented in pure hardware or partly in hardware and partly in software. Alternatively, the embodiment may be implemented on different hardware devices, for example using multiple CPUs.

The foregoing description of the specific embodiments will so fully reveal the general nature of the embodiments herein that others can, by applying current knowledge, readily modify and/or adapt for various applications such specific embodiments without departing from the generic concept. Therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the claims as described herein.

What is claimed is:

1. A method for data transfer in a Non-Volatile Memory Express (NVMe) interface in data integrity extension (DIX) mode, said method comprising:
initiating, by a host, communication with a device, wherein said host and device communicate in data integrity extension mode;
generating, by said device, a plurality of metadata (MD)—logical block (LB) data pairs corresponding to data being communicated; and
transferring said generated MD-LB data pairs, during said communication, by said host and the device, wherein said MD-LB data pairs are transmitted sequentially.

2. The method of claim 1, wherein generating said MD-LB data pairs is based on a data transfer command and further comprises:
receiving, by said device, said data transfer command from said host;
transferring, by said device, at least one logical block corresponding to said data transfer command;
transferring, by said device, a metadata corresponding to said at least one logical block; and
generating said MD-LB data pairs using said at least one logical block and corresponding metadata block, by said device.

3. The method of claim 2,
wherein said device performs an error check of data matching said data transfer command, and
wherein said error check comprises:
calculating a value for protection information for said MD-LB data pair of said data being communicated;
comparing said calculated value of the protection information with said metadata of said MD-LB data pair; and
determining that at least one error is present if the calculated value of the protection information does not match said metadata of said MD-LB data pair.

4. A system for data transfer in a Non-Volatile Memory Express (NVMe) interface in data integrity extension (DIX) mode, said system configured to perform operations comprising:
initiating, by a host of said system, communication with a device of said system, wherein said host and device communicate in data integrity extension mode;
generating, by said device, a plurality of metadata (MD)—logical block (LB) data pairs corresponding to data being communicated; and
transferring said generated MD-LB data pairs, during said communication, by said host and the device, wherein said MD-LB pairs are transmitted sequentially.

5. The system of claim 4, wherein said system is configured to generate said MD-LB data pairs based on a data transfer command by operations comprising:
receiving, by said device, said data transfer command from said host;
transferring, by said device, at least one logical block corresponding to said command;
transferring, by said device a meta-data corresponding to said at least one logical block; and
generating said MD-LB data pairs using said at least one logical block and corresponding metadata block.

6. The system of claim 4,
wherein device is configured to perform an error check of data that matches said data transfer command
wherein said error check comprises:
calculating a value for protection information for said data being communicated;
comparing said calculated protection information value with said metadata in said MD-LB data pair; and
determining that at least one error is present if said protection information value does not match said MD.

7. A method for data transfer between a tangible host and a device using a Non-Volatile Memory Express (NVMe) interface in data integrity extension (DIX) mode, comprising:
initiating, by the host, communication with the device in data integrity extension mode; and
transferring a plurality of metadata (MD)—logical block (LB) data pairs, generated by the device and corresponding to data being communicated, between the host and the device during the communication,
wherein the MD-LB data pairs are transmitted sequentially for each of a plurality of logical blocks,
wherein the logical block includes the data being communicated, and
wherein the metadata includes protection information for the logical block of the data being communicated.

8. The method of claim 7,
wherein the transferring is performed by the host.

9. The method of claim 7,
wherein the transferring is performed by the device.

10. The method of claim 7,
wherein generating the MD-LB data pairs is based on a data transfer command.

11. The method of claim 10, further comprising:
sending the data transfer command from the host to the device;
receiving, by the host, at least one logical block corresponding to the data transfer command from the device; and
receiving, by the host, a metadata block corresponding to the at least one logical block from the device,
wherein the MD-LB data pairs are generated by the device using the at least one logical block and the corresponding metadata block.

12. The method of claim 10,
wherein the device performs an error check of data matching the data transfer command.

13. The method of claim 12, wherein the error check comprises:
calculating a value for protection information for the MD-LB data pair of the data being communicated;
comparing the calculated value of the protection information with the metadata of the MD-LB data pair; and
determining that at least one error is present if the calculated value of the protection information does not match the metadata of the MD-LB data pair.
